(19) United States
(12) Patent Application Publication
(10) Pub. No.: US 2010/0006426 A1
(43) Pub. Date: Jan. 14, 2010

(54) METHOD FOR DEPOSITING AN OXIDE LAYER ON ABSORBERS OF SOLAR CELLS

(75) Inventors: Volker Sittinger, Braunschweig (DE); Florian Ruske, Braunschweig (DE); Bernd Szyszka, Braunschweig (DE)

Correspondence Address: FAEGRE & BENSON LLP;PATENT DOCKETING - INTELLECTUAL PROPERTY, 2200 WELLS FARGO CENTER, 90 SOUTH SEVENTH STREET, MINNEAPOLIS, MN, 55402-3901, US

(73) Assignee: FRAUNHOFER-GESELLSCHAFT ZUR FÖRDERUNG DER ANGEWAND, Munchen (DE)

(21) Appl. No.: 12/443,352

(22) PCT Filed: Sep. 28, 2007
(86) PCT No.: PCT/EP2007/008480

§ 371 Date: Jun. 19, 2009

(30) Foreign Application Priority Data
Sep. 29, 2006 (DE) 10 2006 046 312.9

(51) Int. Cl. C23C 14/34

(52) U.S. Cl. 204/192.29

(57) ABSTRACT

A method for depositing at least one stable, transparent and conductive layer system on chalcopyrite solar cell absorbers. The at least one stable, transparent and conductive layer system may be formed via ionizing PVD (physical vapor deposition) technology by using either high power pulsed magnetron sputtering (HPPMS) or high power impulse magnetron sputtering (HIPIMS).

### CROSS-REFERENCE TO RELATED APPLICATIONS

The present application is a national phase application of PCT application PCT/EP2007/008480 filed pursuant to 35 U.S.C. §371, which claims priority to DE 10 2006 046 312.9 filed Sep. 29, 2006. Both applications are incorporated herein by reference in their entirety.

### TECHNICAL FIELD

The invention relates to a method for depositing at least one stable, transparent and conductive layer system on chalcopyrite solar cell absorbers by means of highly ionizing PVD (physical vapor deposition) technology using high power pulsed magnetron sputtering (HPPMS) or high power impulse magnetron sputtering (HIPIMS).

### BACKGROUND

Current methods for the production of front contact- and buffer layers on chalcopyrite solar absorbers (in short absorbers) suffer from inadequate stability of the front layer system which leads to degradation under the effect of moisture, tested in development by damp heat tests on non-encapsulated modules. The damp heat stability can be measured by measuring the layer resistance of a front contact layer or of the efficiency of the solar cells after storing the solar cells or layers at increased temperature and air humidity.

The reason for the inadequate stability is inter alia the rough absorber surface. Layers deposited thereon do not cover the surface completely which leads to instabilities.

Encapsulated solar modules based on chalcopyrite semiconductors with ZnO:X as transparent front contact (X stands for an element, such as e.g. Al, Ga, In, for doping the oxide) are distinguished by high efficiency and good stability. These modules pass the test of artificial aging at increased temperature and air humidity (damp heat test, 85% moisture, 85° C.) and can be certified according to EN/IEC 61646. However, in the case of non-encapsulated modules, a significant degradation is observed [Klenk, TCO for Thin-film Solar Cells and Other Applications I-II, workshop, Freyburg/Unstrut (2005) p. 71 and 79]. The increase in degradation can be attributed to the increase in surface resistance of the ZnO:X layer [Klaer, Proc. 19^{th} European Photovoltaic Solar Energy Conf., Paris (2004) 1847].

A CdS layer is used within the chalcopyrite solar cell for the production of the heterocontact because it has good band and grating adaptation. Because the low band gap leads to a loss in photocurrent, the CdS layer is applied relatively thinly (˜40 nm) in combination with a thick (˜800 nm) ZnO front contact layer [Potter, Proc., 18^{th} IEEE Photovoltaic Specialists Conf., Las Vegas (1985), 1659]. This takes place by means of chemical bath deposition (CBD) which ensures optimal covering even in the case of very thin layers.

In order to improve the stability of the solar cell, an intrinsic ZnO layer (i-ZnO) is applied between the CdS and the doped ZnO:X layer. Apart from improved damp heat stability, the i-ZnO layer has no influence on the electrical solar cell parameters (Ruckh et al. 25^{th} IEEE Photovoltaic Specialists Conf. (1996) 825; Kessler et al. 16^{th} European Photovoltaic Solar Energy Conf. (2000) 775). Without i-ZnO, the same efficiency is obtained (Ramanathan et al. 31st IEEE Photovoltaic Specialists Conf. (2005)).

Localized defects, such as pinholes within the absorber may lead to short circuits if they come in direct contact with the front contact (Rau 01 et el. Thin Solid Films 387, (2001) 141).

Non-encapsulated solar modules have to date revealed, after the damp heat test, significant degradation which can be attributed mainly to macrograin boundaries (cavities) produced during deposition of the TCO layers on the rough absorber. TCO layers which are deposited on flat substrates, such as glass or silicon, display no degradation, while layers on textured silicon wafers display significant degradation with the same test conditions. This can be attributed to the disrupted microstructure (cavities) of the ZnO:X which is caused by the rough absorber surface (Klenk et al. and Menner et al., TCO for Thin-film Solar Cells and Other Applications III, Workshop Freyburg/Unstrut (2005) p. 79 and p. 71).

It was shown by Kouznetsov et al. (Surface and Coating Technologies 122 (1999) 290) that structures with high aspect ratios can be produced free of cavities by highly ionizing sputtering.

### SUMMARY OF THE INVENTION

The present invention pertains to a method which enables the production of solar cells, which have front contact- or buffer layers with improved stability under the influence of moisture and/or heat (damp heat stability).

According to the invention, a method for depositing at least one transparent, conductive oxide layer on a solar cell which has at least one absorber layer for absorption of light is provided, the deposition of the oxide layer being effected by a pulsed magnetron sputtering method.

### DETAILED DESCRIPTION

The pulse frequency is in the range of at least 100 Hz, preferably in the range 1,000 to 100 Hz, very particularly in the range 100 to 500 Hz. The duty cycle is less than 5%. The pulse lengths are less than 200 ms, particularly 10 to 200 μs, very particularly 30 to 150 μs.

The sputtering method is advantageously a high power pulsed magnetron sputtering (HPPMS) and/or high power impulse magnetron sputtering (HIPIMS). One embodiment of the method provides that the power density of the particle beam is at least 0.5 kW/cm², preferably at least 0.75 kW/cm², very particularly at least 1 kW/cm².

By using a vacuum deposition method of this type, a higher degree of ionization and/or increased kinetic energy of the layer-forming particles is achieved when impinging on the substrate to be coated, thereby ensuring increased mobility of the adsorbed species on the surface of the substrate.

As a consequence, the formation of defects, in particular the growth of macrograin boundaries at the grain boundaries of the absorber to be coated is suppressed. As a result, increased stability of the TCO layer deposited on rough substrates is achieved in the damp heat test.

Improved damp heat stability is a crucial advantage for the industrial manufacture of solar modules since the demands upon the encapsulation of the modules can be reduced, i.e. savings can be made for the encapsulation. In particular, this is an advantage in the production of solar modules on flexible substrates, such as polymer films and metal foils, since encapsulation with glass is impossible. Instead, recourse must be made to foils or a thin-film encapsulation in order to maintain the flexibility.

In a preferred embodiment, the oxide layer is applied as a front contact layer of the solar cell so that the oxide layer forms the sealing upper layer of the solar cell. The front contact layer can be applied at a thickness of 1 nm and 200 nm, preferably between 100 nm and 1.5 μm, preferably between 300 nm and 1,000 nm, particularly between 400 nm and 800 nm, according to for how long the sputtering process is effected.

The material from which the front contact layer is formed by the sputtering process may contains oxides which are formed from one or more of zinc oxide, indium oxide, tin oxide, zinc-tin mixtures (stannate), titanium oxide and/or mixtures hereof.

Furthermore, the oxide materials may be doped to increase the conductivity and/or to adjust specific electrical properties. According to the invention, the doping is not restricted to specific doping materials but can be selected according to the desired result from the materials known to the person skilled in the art, but including aluminium, gallium, indium, boron, fluorine, antimony, niobium and/or mixtures hereof. The dopant is selected according to the oxide matrix which is used. For example for a zinc oxide matrix, Al, Ga, In and/or B may be used as dopant. For an indium oxide matrix, tin (ITO) or zinc (IZO) may be used as dopant, Tin oxide may be doped with the elements F and/or Sb. Titanium oxide may be doped with Nb. In an advantageous development, the degree of doping is between 0.2 and 5% by atom.

In an alternative embodiment of the invention, the oxide layer is configured as a buffer layer between the absorber and a further layer situated thereabove. According to the invention the buffer layer is first applied on the absorber and subsequently at least one further layer is deposited above the buffer layer so that the buffer layer is enclosed between the absorber and the further layer. This alternative embodiment may provide the same advantages mentioned for applying the layer as front layer.

In principle, any buffer layer thickness can be used with the method according to the invention. In one embodiment, however, the buffer layer is applied at a thickness between 1 nm and 200 nm, preferably between 10 and 100 nm, very particularly between 10 and 50 nm.

Due to the increased mobility of the adsorbed species, complete covering of the embossed three-dimensional structure of the absorber is achieved even in the case of thin buffer layers (d<100 nm), in particular layers with a layer thickness of less than 50 nm. As a result, a suitable heterotransition is produced.

In particular, advantageous results are achieved as a result if the buffer layer contains materials including one or more of sulphides and/or selenides of the elements indium, tungsten, molybdenum, zinc, magnesium, indium oxide, zinc-magnesium oxide and/or mixtures hereof. For example, a mixture zinc-magnesium sulphide and/or -selenide may be included.

By applying the method according to the invention, the use of cadmium in the buffer layer may be dispensed with. An advantage of dispensing with the CdS layer produced by chemical bath depositionis that a substantial simplification is achieved during production of solar modules since the modules no longer require being brought to atmospheric pressure between production of the absorber and the TCO deposition.

The method according to the invention can be applied if the solar cell has an absorber made of chalcopyrite. The absorber according to the invention also includes PV absorbers, in particular rough absorbers, also thin-film absorbers, such as CIGS, CdTe, amorphous Si, microcrystalline Si or made of poly- or monocrystalline silicon.

According to the invention, a solar cell is likewise provided in which at least the front contact- and/or the buffer layer is produced according to a method as described above.

The present invention is described in more detail with reference to the subsequent example without restricting the invention.

### EXAMPLE

To test the method, ZnO:Al layers were applied by means of an HPPMS generator on delivered mini modules in the format 10×10 cm², with the layer structure glass/Mo/Cu—In—Ga—S absorber/CdS/i-ZnO. The same absorbers were provided likewise by the testing institute with an optimized standard DC sputtered ZnO:Al layer. Both layers had the same ZnO—Al layer thickness. Subsequently, the non-encapsulated mini modules produced were subjected to a damp heat test (85% relative humidity at 85° C.).

The results of the change in surface resistance or efficiency are reproduced in table 1.

TABLE 1

| | |
|---|---|
| HPPMS sample | DC reference sample |

| Damp heat time | Rₛₕ | η | Rₛₕ | η |
|---|---|---|---|---|
| [h] | [Ω] | [%] | [Ω] | [%] |
| 0 | 7.1 | 12.7 | 12.8 | 12.5 |
| 50 | 8.7 | 10.1 | 18 | 11.9 |
| 212 | 12.4 | 9.2 | 27 | 4.9 |
| 999 | 27.7 | 4.6 | 75.4 | — |

Table 1 shows that the ZnO:Al layer produced under non-optimized conditions by means of HPPMS technology displays an improved damp heat stability. The testing is effected according to DIN EN 61646, in particular page 20.

1. A method for depositing at least one transparent, conductive oxide layer on a solar cell which has at least one absorber layer, the method comprising:
depositing the at least one transparent, conductive oxide layer using
pulsed magnetron sputtering with a pulse frequency of at least 100 Hz and a power density of at least 0.5 kW/cm².

2. The method according to claim 1, wherein the pulse frequency is in the range of 100 Hz to 1,000 Hz.

3. The method according to claim 1, wherein a pulse length of the pulsed magnetron sputtering is ≦200 μs.

4. The method according to claim 1, wherein the sputtering method comprises high power pulsed magnetron sputtering or high power impulse magnetron sputtering.

5. The method according to claim 1 wherein the power density is at least 0.75 kW/cm.

6. The method according to claim 1, wherein the oxide layer is applied as a front contact layer of the solar cell.

7. Method according to claim 6, wherein the front contact layer is applied at a thickness between 100 nm and 1.5 μm.

8. The method according to claim 6, wherein the front contact layer contains oxides selected from the group consisting of zinc oxide, indium oxide, tin oxide, zinc-tin mixtures, titanium oxide and mixtures hereof.

9. The method according to claim 8, wherein the oxides are doped.

10. The method according to claim 9, wherein the doping materials are selected from the group consisting of aluminium, gallium, indium, boron, fluorine, antimony, niobium and mixtures hereof.

11. The method according to claim 9, wherein the doping is between 0.2 and 5% by atom.

12. The method according to claim 1, wherein on the oxide layer is applied as a buffer layer between the absorber and a further layer situated thereabove.

13. The method according to claim 12, wherein the buffer layer is applied at a thickness between 1 nm and 200 nm.

14. The method according to claim 12, wherein the buffer layer contains materials selected from the group consisting of sulphides and/or selenides of the elements indium, tungsten, molybdenum, zinc, magnesium, indium oxide, zinc-magnesium oxide and mixtures hereof.

15. The method according to claim 12, wherein the buffer layer is free of cadmium.

16. The method according to claim 1, wherein the solar cell includes an absorber comprising CIGS, CdTe, amorphous Si, microcrystalline Si, or poly- or monocrystalline silicon.

17-18. (canceled)

19. The method according to claim 1, wherein the pulse frequency is in the range of 100 Hz to 500 Hz.

20. The method according to claim 3, wherein the pulse length is in the range of 10 to 200 μs.

21. The method according to claim 1, wherein the power density is at least 1 kW/cm².

22. The method according to claim 6, wherein the front contact layer is applied at a thickness between 300 nm and 1000 nm.
